(19) United States
(12) Patent Application Publication
(10) Pub. No.: US 2026/0282496 A1
(43) Pub. Date: Sep. 17, 2026

(54) TRANSISTOR

(71) Applicants: STMicroelectronics (Crolles 2) SAS, Crolles (FR); STMicroelectronics (Rousset) SAS, Rousset (FR)

(72) Inventors: Siddhartha DHAR, Grenoble (FR); Stephane MONFRAY, Eybens (FR); Alain FLEURY, Barberaz (FR); Franck JULIEN, La Penne sur Huveaune (FR)

(73) Assignees: STMicroelectronics (Crolles 2) SAS, Crolles (FR); STMicroelectronics (Rousset) SAS, Rousset (FR)

(21) Appl. No.: 19/678,834

(22) Filed: May 15, 2026

Related U.S. Application Data
(62) Division of application No. 18/197,909, filed on May 16, 2023, now abandoned.

(30) Foreign Application Priority Data
May 19, 2022 (FR) FR2204759

(51) Int. Cl. H10D 64/27; H10D 30/67; H10D 64/01; H10D 84/01; H10D 84/03; H10D 84/83

(52) U.S. Cl. CPC H10D 64/516; H10D 30/6736; H10D 64/01; H10D 84/0144; H10D 84/038; H10D 84/83; H10D 64/518

(57) ABSTRACT

A transistor includes a semiconductor layer with a stack of a gate insulator and a conductive gate on the semiconductor layer. A thickness of the gate insulator is variable in a length direction of the transistor. The gate insulator includes a first region having a first thickness below a central region of the conductive gate. The gate insulator further includes a second region having a second thickness, greater than the first thickness, below an edge region of conductive gate.

### CROSS REFERENCE TO RELATED APPLICATIONS

This application is a divisional of United States Application for Patent No. 18/197,909, filed May 16, 2023, which claims the priority benefit of French Application for Patent No. FR2204759, filed on May 19, 2022, the contents of which are hereby incorporated by reference in their entireties to the maximum extent allowable by law.

### TECHNICAL FIELD

The present disclosure generally concerns electronic components and more particularly field-effect transistors of Metal Oxide Semiconductor Field Effect Transistor (MOSFET) type.

### BACKGROUND

MOSFET transistors are field-effect transistors comprising a conductive gate, for example metallic, electrically-insulated from a semiconductor substrate by a dielectric layer called gate insulator.

Various embodiments of MOSFET transistors have already been provided.

It would be desirable to at least partly overcome certain disadvantages of known embodiments of MOSFET transistors.

The improvement of the electric performance of MOSFET transistors intended for radio frequency (RF) signal switching applications, also called RF switches, is here more particularly considered.

### SUMMARY

For this purpose, an embodiment provides a transistor comprising, on a semiconductor layer, a stack of a gate insulator and of a conductive gate, wherein the thickness of the gate insulator is variable in the length direction of the transistor, the gate insulator comprising a first region having a first thickness in front of a central region of the conductive gate, and a second region having a second thickness, greater than the first thickness, in front of the gate edges.

According to an embodiment, the thickness of the gate insulator varies progressively between the first and second regions.

According to an embodiment, the gate insulator exhibits a step between the first and second regions.

According to an embodiment, the first region extends along a length in the range from 110 nm to 130 nm.

According to an embodiment, the second region is divided into two portions located on either side of the first region, each of the portions of the second region extending along a length in the range from 10 nm to 30 nm.

According to an embodiment, the difference between the first thickness and the second thickness is greater than or equal to 2 nm.

According to an embodiment, the conductive gate is coated, on its sides, with an oxide layer.

Another embodiment provides a radio frequency switch comprising a transistor such as described hereabove.

Still another embodiment provides an integrated circuit comprising a first transistor such as described hereabove, a second transistor comprising a gate insulator layer of constant thickness equal to the first thickness, and a third transistor comprising a gate insulator layer of constant thickness equal to the second thickness.

Still another embodiment provides a method of manufacturing a transistor such as described hereabove, comprising the following successive steps: a) deposition of a gate insulator layer of thickness e1 on an upper surface of a semiconductor layer; b) forming of a conductive gate on top of and in contact with a portion of the gate insulator layer; and c) thermal oxidation of the gate insulator layer so that the gate insulator layer reaches a thickness e2 greater than e1 in front of the edges of the conductive gate and that it remains at the first thickness in front of the center of the conductive gate.

According to an embodiment, the method comprises the following successive steps: a) forming of a first gate insulator layer of thickness e3 on an upper surface of a semiconductor layer; b) local removal of the first gate insulator layer from the first region over a strip of width L1; c) forming of a gate insulator layer of thickness e4 smaller than e3 on the upper surface of the semiconductor layer in the first region; and d)forming of a conductive gate in front of a strip of width L greater than L1 comprising said strip of width L1.

According to an embodiment, the method further comprises the simultaneous forming: of a first additional transistor comprising a gate insulator layer of constant thickness e4 in the channel length direction of the transistor; and of a second additional transistor comprising a gate insulator layer of constant thickness e3 in the channel length direction of the transistor.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIGS. 1A, 1B, 1C, and 1D are cross-section views partially and schematically illustrating successive steps of an example of a method of manufacturing a transistor according to a first embodiment;

FIGS. 2A, 2B, 2C, 2D, 2E, and 2F are cross-section views partially and schematically illustrating successive steps of an example of a method of manufacturing a transistor according to a second embodiment;

FIG. 3 illustrates an alternative implementation of the method according to the second embodiment; and

FIGS. 4A and 4B illustrate an alternative implementation of the method according to the first embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the various possible applications of the described transistors have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms "front", "back", "top", "bottom", "left", "right", etc., or to relative positional qualifiers, such as the terms "above", "below", "upper", "lower", etc., or to qualifiers of orientation, such as "horizontal", "vertical", etc., reference is made to the orientation shown in the figures.

Unless specified otherwise, the expressions "around", "approximately", "substantially" and "in the order of" signify within 10%, and preferably within 5%.

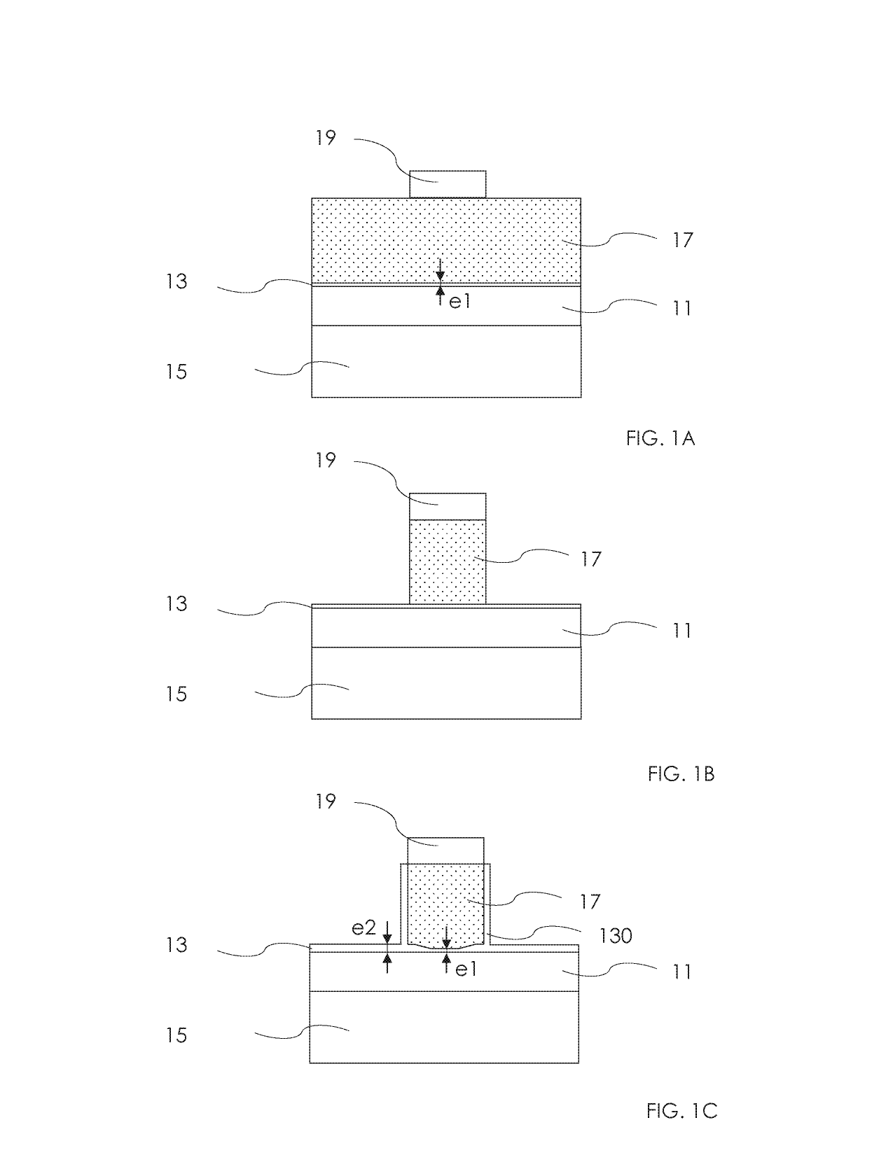

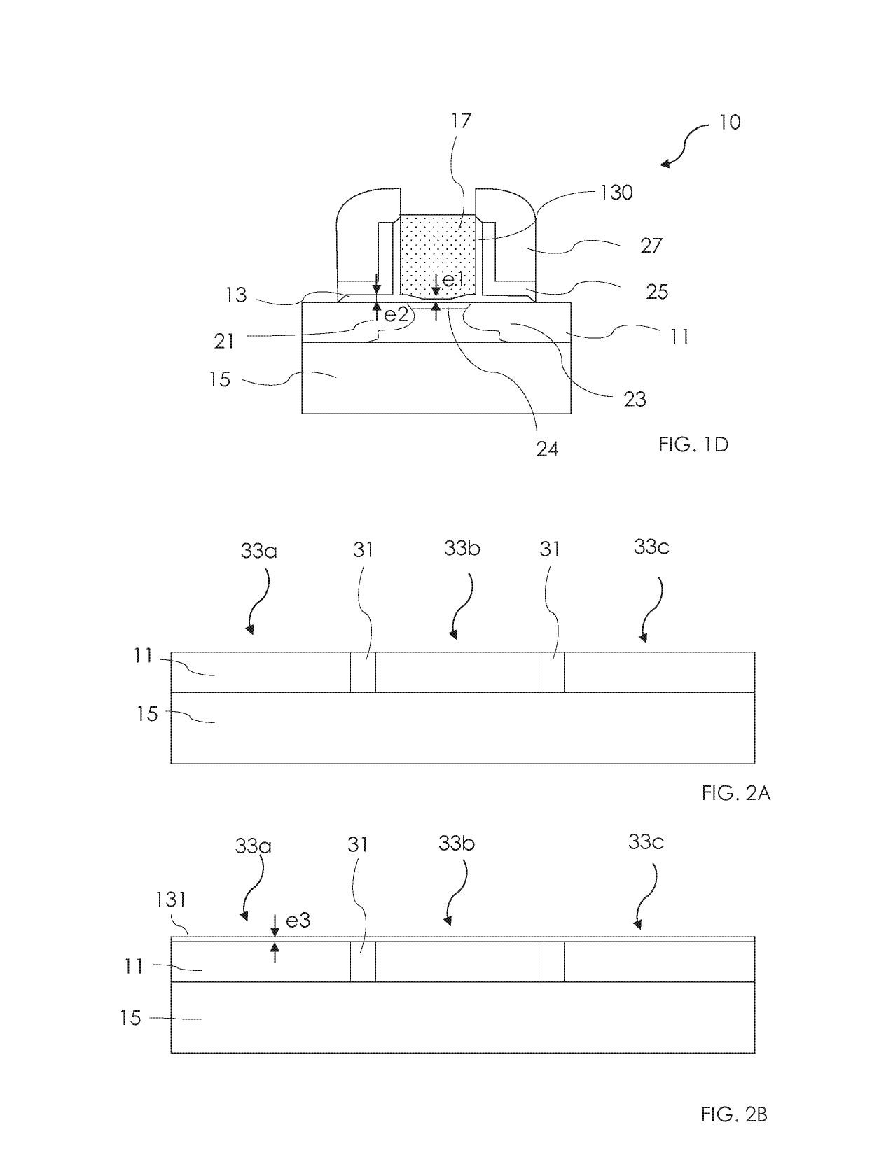

FIGS. 1A to 1D are cross-section views partially and schematically illustrating successive steps of an example of a method of manufacturing a MOSFET-type transistor 10 according to a first embodiment.

FIG. 1A more particularly shows a structure comprising a semiconductor layer 11 topped with a dielectric layer 13 also called gate insulator layer. The structure of FIG. 1A further comprises a conductive layer 17, also called gate layer, on gate insulator layer 13. As an example, the structure comprises a buried insulating layer 15, under semiconductor layer 11. Layers 11 and 15 for example correspond to a stack of a semiconductor on insulator (SOI) type substrate.

As an example, in FIG. 1A, gate insulator layer 13 is on top of and in contact with semiconductor layer 11 and conductive gate layer 17 is on top of and in contact with insulating layer 13. Semiconductor layer 11 is, for example, on top of and in contact with buried insulating layer 15.

As an example, conductive gate layer 17 is topped with a layer 19. As an example, layer 19 corresponds to a masking layer for an etch step that will be detailed in relation with FIG. 1B. Layer 19 is, for example, a resin. In FIG. 1A, masking layer 19 forms a block having its dimensions, in top view, corresponding to the final dimensions desired for the gate of transistor 10.

Semiconductor layer 11 is, for example, made of silicon, for example, of single-crystal silicon. Semiconductor layer 11 has, for example, a thickness in the range from 10 nm to 500 nm, for example from 50 nm to 200 nm, for example, in the order of 60 nm or in the order of 160 nm.

As an example, gate insulator layer 13 is made of silicon dioxide (SiO₂) and has, for example, in the structure illustrated in FIG. 1A, a thickness e1 in the range from 1 nm to 10 nm, for example in the range from 2 nm to 6 nm, for example in the order of 5 nm.

As an example, buried oxide layer 15 is made of oxide, for example, of silicon dioxide (SiO₂). Buried insulating layer 15 has, for example, a thickness in the range from 100 nm to 400 nm, for example, from 100 nm to 250 nm, for example in the order of 200 nm.

As an example, conductive gate layer 17 is made of doped polysilicon. Layer 17 has, for example, a thickness in the range from 30 nm to 300 nm, for example in the range from 50 nm to 100 nm, for example in the range from 80 nm to 90 nm.

In practice, the structure illustrated in FIG. 1A may be supported by a support substrate, not shown, for example made of a semiconductor material, for example of silicon, that is associated with the SOI substrate. Buried insulating layer 15 is, for example, on top of and in contact with an upper surface of the support substrate.

FIG. 1B corresponds to a structure obtained at the end of a step of etching of the conductive gate layer 17 of the structure illustrated in FIG. 1A. During this step, conductive gate layer 17 is etched so that only the portion of gate layer 17 located under masking layer 19 remains, the portions of conductive gate layer 17 which are not covered with masking layer 19 being removed. As an example, the etch method used etches the gate conductor material selectively over the material of gate insulator layer 13. Gate insulator layer 13 then plays the role of a barrier to the etching so that the etching stops on the upper surface of layer 13. At the end of this step, the non-etched portion of layer 17 forms the conductive gate of transistor 10. As an example, at the end of this etch step, conductive gate 17 has a length (defining the channel length of the transistor – that is, the source-drain distance – shown in the figure in left to right direction) in the range from 50 nm to 300 nm, for example in the range from 100 nm to 200 nm, for example in the order of 140 nm. Conductive gate 17 has, for example, a width (defining the channel width of the transistor – in the figure extending into and out of the illustration) in the range from 1 µm to 10 µm, for example in the order of 5 µm.

FIG. 1C corresponds to a structure obtained at the end of a step of thermal oxidation of the structure illustrated in FIG. 1B.

During this step, the structure illustrated in FIG. 1C undergoes an oxidation. Thus, gate insulator layer 13 thickens in the regions where it is not covered with conductive gate 17. Gate insulator layer 13 further thickens, during this step, between conductive gate 17 and semiconductor layer 11 in regions located at and near the edge of conductive gate 17. The thickness of gate insulator layer 13 however remains unchanged in front of a central portion or region of conductive gate 17, protected from oxidation by gate 17. Still during this step, an oxide layer 130 is, for example, formed on the lateral edges of conductive gate 17.

As an example, gate insulator layer 13 is locally thickened by from 1 nm to 10 nm, for example by from 2 nm to 4 nm, in the regions where it is not covered with conductive gate 17. Thus, at the end of the thermal oxidation step, gate insulator layer 13 has a thickness e2 greater than e1, for example, in the range from 1 nm to 15 nm, for example in the range from 3 nm to 8 nm, for example in the order of 7 nm, in the regions where it is not covered with conductive gate 17.

As an example, between conductive gate 17 and semiconductor layer 11, in regions located in the vicinity of the edge of conductive gate 17, gate insulator layer 13 has a thickness decreasing from the lateral side of conductive gate 17 towards the center of conductive gate 17. More particularly, the thickness of the gate insulator layer decreases substantially continuously from thickness e2 to thickness e1, from the edges of conductive gate 17 to a central portion or region of the conductive gate, in the channel length direction of the transistor.

As an example, the thermal oxidation step is carried out at a temperature in the range from 300°C to 1,200°C, for example in the range from 500°C to 1,000°C, for example, in the order of 900°C. As an example, the oxidation step is carried out for a duration in the range from 1 s to 2 min, for example in the range from 20 s to 1 min, for example, in the order of 35 s. As an example, the thermal oxidation step is carried out under water vapor.

FIG. 1D shows an example of the transistor 10 obtained at the end of the manufacturing method.

Transistor 10 comprises, for example, a source region 21 and a drain region 23 formed in semiconductor layer 11. Source and drain regions 21 and 23 are, for example, laterally separated from each other by a body region. An upper portion of the body region forms the channel-forming region 24 of transistor 10. Conductive gate 17 is located above channel-forming region 24.

As an example, the source 21, drain 23 and body regions are flush with the upper surface of semiconductor layer 11.

Transistor 10 is, for example, an N-channel MOS transistor (NMOS), that is, a transistor having its source and drain regions 21 and 23 N-type doped, for example, doped with arsenic or phosphorus atoms, while the body region is P-type doped, for example, doped with boron atoms.

As a variant, transistor 10 is, for example, a P-channel MOS transistor (PMOS), that is, a transistor having its source and drain regions 21 and 23 P-type doped, for example, doped with boron atoms while the body region is N-type doped, for example doped with arsenic or phosphorus atoms.

As an example, transistor 10 comprises insulating spacers 25, 27 capable of coating the sides of gate 17 and the side of gate insulator 13. Insulating spacers 25 are, for example, made of silicon nitride (Si₃N₄) and insulating spacers 27 are, for example, made of silicon nitride (Si₃N₄).

Transistor 10 may be laterally surrounded with an insulating trench, not shown, for example of Shallow Trench Isolation (STI) type. The insulating trench thus forms a ring around transistor 10. The insulating trench extends, for example, vertically through semiconductor layer 11 to reach buried insulating layer 15. The insulating trench enables to electrically insulate transistor 10 from other components (not visible in the drawing) of the device.

In this example, the thickness of gate insulator layer 13 gradually increases from the location in front of a central portion or region of conductive gate 17 to the lateral edges of the gate.

The thickness of gate insulator layer 13 and more particularly its gradual variation is, for example, controlled by the temperature and/or the pressure and/or the time of the thermal oxidation step described in relation with FIG. 1C.

At the end of the thermal oxidation step described in relation with FIG. 1C, and to obtain the transistor illustrated in FIG. 1D, source and drain regions 21 and 23 are implanted in semiconductor layer 11, insulating spacers 25, 27 are formed on either side of conductive gate 17, mask layer 19 is removed.

An advantage of the embodiment described in relation with FIGS. 1A to 1D results from the variable thickness, continuously decreasing towards the central portion of the gate from the lateral edges of the gate, of the gate insulator layer 13 of the transistor. The provision of a relatively thick gate insulator (thickness e2) under a peripheral portion of gate 17 enables to decrease the parasitic capacitance COFF, in the off state, of the transistor, between semiconductor layer 11 and gate 17. The maintaining of a relatively low thickness of the gate insulator (thickness e1) under a central portion of gate 17 however enables to decrease or not too significantly increase the on-state resistance RON of the transistor. A particularly advantageous RON/COFF tradeoff can thus be obtained, particularly for RF signal switching applications. Transistors 10 are advantageously RF switches, for example intended to operate at frequencies in the range from 3 kHz to 300 GHz, for example from 100 MHz to 10 GHz, for example in the order of one GHz.

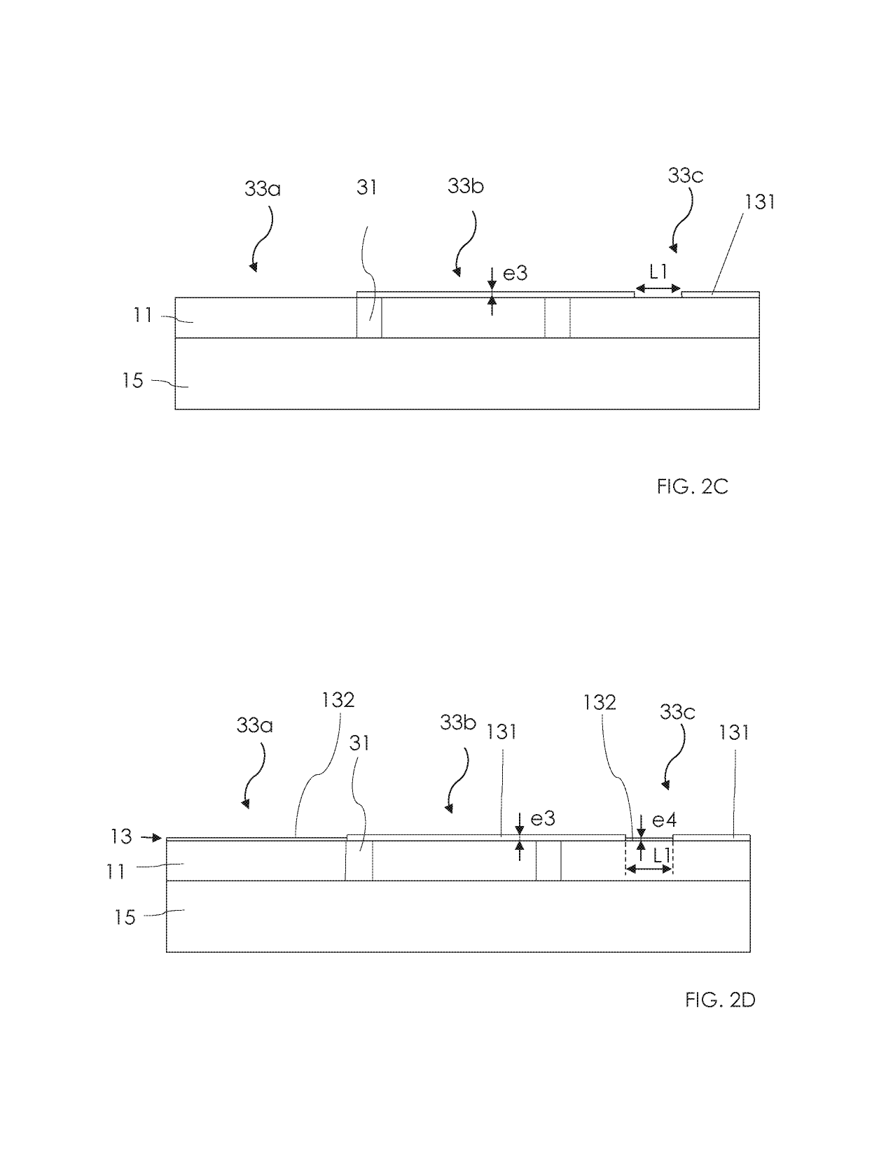

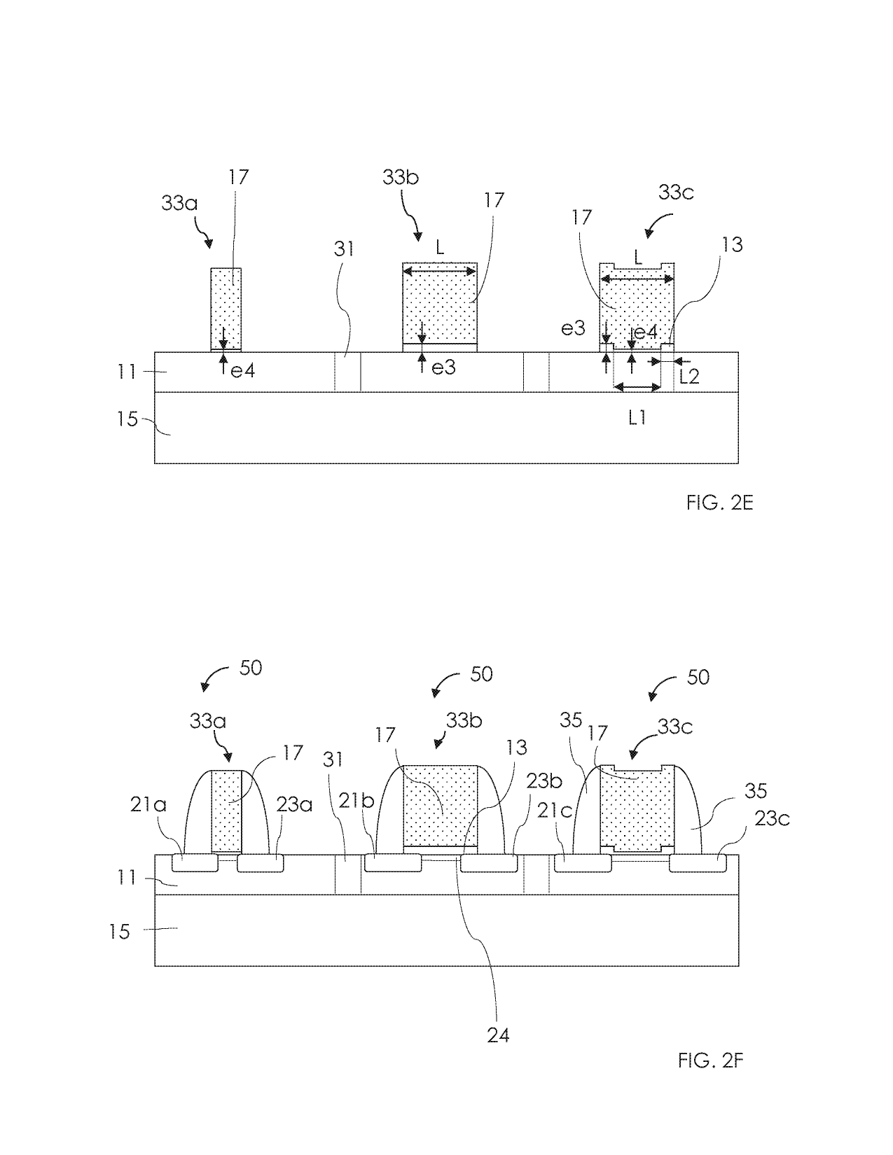

FIGS. 2A to 2F are cross-section views partially and schematically illustrating successive steps of an example of a method of manufacturing a transistor 50 or 51 according to a second embodiment.

FIG. 2A more particularly illustrates a structure comprising a semiconductor layer 11 on top of and in contact with a buried oxide layer 15. The layers 11 and 15 of FIG. 2A are, for example, identical to the layers 11 and 15 illustrated in FIG. 1A.

Trenches 31 are, for example, formed in semiconductor layer 11 and extend, for example, from the upper surface of semiconductor layer 11 to its lower surface in the orientation of FIG. 2A. As an example, trenches 31 are formed by etching or by sawing.

At the end of their forming, trenches 31 are, for example, filled with an insulator, for example, made of a same material as layer 15, for example, of silicon dioxide.

Trenches 31, emerging into buried oxide layer 15, delimit in semiconductor layer 11 wells intended to comprise transistors of different types. In FIG. 2A, two trenches 31 are shown so that the illustrated structure is divided into three areas or wells 33a, 33b, and 33c. In practice, at the scale of a semiconductor wafer, the structure may comprise a number of trenches 31 different from two.

Although this is not illustrated in FIG. 2A and similarly to what has been described in relation with FIG. 1A, the structure illustrated in FIG. 2A may supported on a support substrate associated with an SOI substrate.

In this embodiment, it is provided to take advantage of the fact that, on a single semiconductor wafer, a plurality of transistor types can be formed simultaneously. Indeed, within a same semiconductor wafer, it is possible to simultaneously form so-called gate oxide 1 (GO1) transistors having a relatively low thickness of their gate insulator (for example, in the order of 2 nm) and so-called gate oxide 2 (GO2) transistors having a relatively high thickness of their gate insulator (that is, greater than the gate insulator thickness of transistors GO1, for example, in the order of 5 nm).

In the manufacturing method illustrated in FIGS. 2A to 2F, it is provided to simultaneously form GO1 transistors, GO2 transistors, and transistors 50 where the thickness of gate insulator 13 is not constant in the channel length direction of the transistor. In FIG. 2A, area 33a corresponds to the area where the GO1 transistors are formed, area 33b corresponds to the area where the GO2 transistors are formed, and area 33c corresponds to an area where transistors 50 are formed.

FIG. 2B illustrates a structure obtained at the end of a step of forming of a first gate insulator layer 131 on the upper surface of semiconductor layer 11. As an example, gate insulator layer 131 is formed by oxidation of the upper surface of layer 11. Gate insulator layer 131 continuously extends, for example, with a substantially uniform thickness over the entire upper surface of semiconductor layer 11.

At the end of this step, gate insulator layer 131 has a thickness e3, for example in the range from 2 nm to 10 nm, for example, in the range from 2 nm to 4 nm.

As an example, layer 131 is made of the same material as the layer 13 of FIG. 1A, for example, silicon oxide.

FIG. 2C illustrates a structure obtained at the end of a step of partial removal of layer 131 from the structure illustrated in FIG. 2B, specifically in the area 33a and in a portion of the area 33c.

At the end of the step of forming of layer 131, the layer 131 is locally removed, for example, by photolithography and etching to form openings in layer 131. More precisely, in this example, layer 131 is removed from the entire surface of area 33a. During this same step, layer 131 is further removed from a portion of the surface of area 33c, over a strip of width L1 smaller than the channel length of the future transistor 50, said strip extending in front of a central portion or region of the channel region of the transistor, along a length substantially equal to the channel width of the transistor. As an example, width L1 is in the range from 50 nm to 300 nm, for example, in the range from 70 nm to 150 nm, for example in the range from 110 nm to 130 nm.

FIG. 2D illustrates a structure obtained at the end of a step of forming of a second gate insulator layer 132 on the upper surface of the structure illustrated in FIG. 2D only in front of the openings formed in layer 131. Layer 132 is, for example, formed by oxidation of the upper surface of the structure of FIG. 2C.

During this step, layer 132 is, for example, formed with a thickness e4 smaller than the thickness e3 of layer 131. As an example, thickness e4 is in the range from 1 nm to 10 nm, for example, in the range from 2 nm to 6 nm, for example, in the order of 2 nm.

As an example, layer 132 only grows in front of the regions where layer 131 has previously been removed during the step of FIG. 2C. Thus, in this example, at this step, the thickness of layer 131 remains substantially unchanged.

First gate insulator layer 131 and second gate insulator layer 132 correspond to different portions of gate insulator layer 13.

At the end of this step, gate insulator layer 13 has: in area 33a, a thickness corresponding to thickness e4; in area 33b, a thickness corresponding to a thickness e3; and in area 33c, a thickness corresponding to thickness e3 except along length L1 where it corresponds to thickness e4.

Thickness e4 correspond to the gate insulator thickness of the GO1 transistors. Thickness e3 corresponds to the gate insulator thickness of the GO2 transistors.

FIG. 2E illustrates a structure obtained at the end of a step of forming of the gates 17 of transistors GO1, GO2, and 50.

During this step, a conductive gate 17 is formed in each of the three areas 33a, 33b, 33c. The forming of conductive gates 17 is, for example, performed by a continuous deposition of a conductive gate layer similar to the layer 17 illustrated in FIG. 1A, followed by a local removal thereof, for example, by photolithography and etching.

As an example, conductive gates 17 are conformally deposited, that is, in area 33c, one finds at the surface of conductive gate 17 a step corresponding to the step formed in across the thickness of gate insulator 13.

As an example, the conductive gates are formed on top of and in contact with gate insulator layer 13. Conductive gates 17 for example have a thickness in the range from 30 nm to 300 nm, for example in the range from 50 nm to 200 nm, for example, in the order of 60 nm or 160 nm.

As an example, conductive gate 17 extends, in area 33c, along a length L greater than L1, for example in the range from 50 nm to 300 nm, for example in the range from 100 nm to 200 nm, for example in the order of 140 nm. Conductive gate 17 extends, for example, in area 33b, along the same length L as in area 33c. As an example, conductive gate 17 extends, in area 33a, along a length smaller than length L, for example, in the range from 5 nm to 100 nm, for example in the range from 10 nm to 50 nm, for example in the order of 13 nm.

As an example, the forming of conductive gates 17 is followed by a step of etching of gate insulator layer 13 outside of the location in front of conductive gates 17. During this step, the gate insulator portions 13 which are not in front of the conductive gates are removed.

At the end of these steps, in third area 33c, gate insulator layer 13 has a thickness e4 in a region in front of a central portion of region of conductive gate 17, across width L1, and has a thickness e3 in front of a peripheral portion of conductive gate 17, that is, in front of the edges of conductive gate 17. The central longitudinal axis of the strip of width L1 is, for example, vertically aligned with the central axis of gate 17. Thus, the gate insulator has a thickness e3 on either side of the location in front of the center of conductive gate 17 along a length L2 equal to half difference L-L1.

As an example, length L2 is in the range from 5 nm to 150 nm, for example in the range from 5 nm to 30 nm, for example in the range from 10 nm to 30 nm.

FIG. 2F corresponds to a structure obtained at the end of steps of forming of insulating spacers 35 on either side of conductive gates 17 in each of areas 33a, 33b, and 33c and of forming of source and drain regions 21, 23 in the semiconductor layer 11 of the structure illustrated in FIG. 2E.

As an example, each conductive gate is covered, on its lateral sides, with spacers 35.

As an example, spacers 35 are similar to the association of the spacers 25 and 27 described in relation with FIG. 1D. More particularly, in each of the three areas 33a, 33b, and 33c, a source region 21a, 21b, and 21c and a drain region 23a, 23b, and 23c are implanted in semiconductor layer 11.

The dopant element concentrations in the source region 21a and in the drain region 23a of the GO2-type transistors may be different from the dopant element concentrations respectively in the source region 21b and in the drain region 23b of the GO1-type transistors.

The dopant element concentrations in source region 21c and in drain region 23c correspond, preferably, to the dopant element concentrations respectively in the source region 21b and in the drain region 23b of the GO2-type transistors or to the dopant element concentrations respectively in the source region 21a and in the drain region 23a of the GO1-type transistors. This enables not to require an additional implantation step with respect to the steps of implantation of the source and drain regions of the GO1 and GO2 transistors. As a variant, the dopant element concentrations in source region 21c and in drain region 23c are different from the dopant element concentrations of source regions 21a, 21b and of drain regions 23a, 23b.

As an example, the forming of source and drain regions 21 and 23 is performed after the forming of spacers 35, by using the gate and the spacers as an implantation mask.

As a variant, the source and drain regions 21 and 23 each comprise an extension region, relatively lightly doped, formed after the etching of the conductive gates (FIG. 2E) and before the forming of spacers 35 (FIG. 2F), by using the gate as an implantation mask, and a more heavily-doped region, formed after the forming of spacers 35, by using the gate and the spacers as an implantation mask. The more heavily-doped region defines the source, respectively drain, contacting region of each transistor. The more lightly-doped region extends between the more heavily-doped region and the channel-forming region of the transistor.

As an example, source and drain regions 21 and 23 are implanted, for example, by local doping. As an example, the source and drain regions are doped, for example, with arsenic or phosphorus atoms for an N doping and doped with boron atoms for a P doping.

The source and drain regions are laterally separated from each other by a body region. An upper portion of the body region forms the channel-forming region 24 of the transistor.

As an example, the source and drain regions are flush with the upper surface of semiconductor layer 11.

At the end of this step, insulating trenches, for example similar to the tranches described in FIG. 1D, are formed. As an example, the insulating trenches are formed around the transistors similarly to what has been described in relation with FIG. 1D.

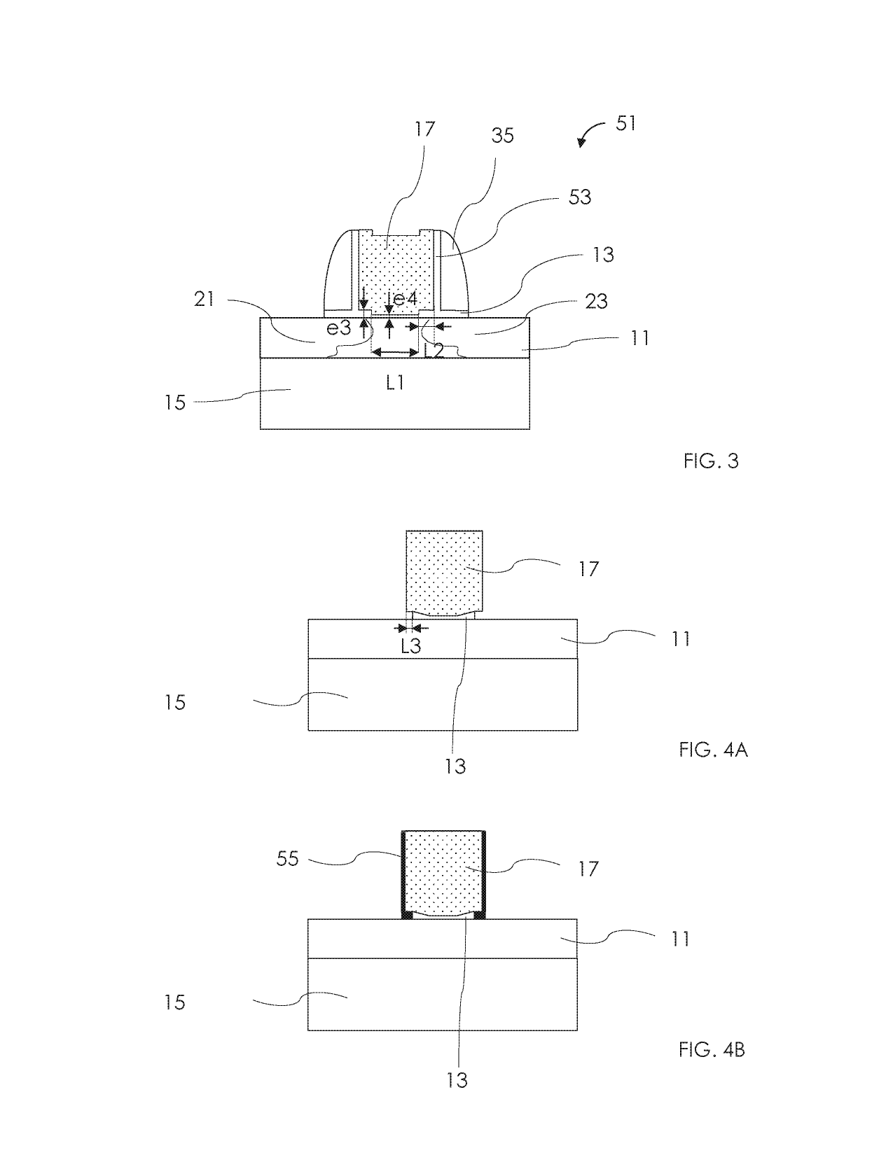

FIG. 3 shows a variant of the transistor obtained at the end of the method according to the second embodiment.

The transistor 51 illustrated in FIG. 3 is similar to the transistor such as it would be obtained from the transistor 50 of FIG. 2F and at the end of the step of forming of the insulating trenches, with the difference that is comprises, on the lateral sides of conductive gate 17, an oxide layer 53, for example similar to the layer 130 illustrated in FIG. 1D.

The oxide layer 53 coating the sides of conductive gate 17 is, for example, deposited during an additional step of the manufacturing method. As an example, oxide layer 53 is formed between the step of forming of conductive gate 17 and the step of forming of spacers 35. AS an example, oxide layer 53 is made of the same material as gate insulator layer 13.

The embodiment described in relation with FIGS. 2A to 2F also enables to obtain a particularly advantageous RON/COFF tradeoff, particularly for RF signal switching applications, by means of a gate insulator layer of variable thickness, decreasing towards the central portion of the gate.

Another advantage of the method of the second embodiment is that it is compatible with methods of manufacturing usual transistors. Indeed, during this method, no step is added with respect to existing methods of simultaneously manufacturing the GO1 and GO2 transistors. The forming of transistor 50 or 51 is thus co-integrated with the forming of the GO1 and GO2 transistors. In other words, the method of the second embodiment enables to manufacture a device comprising, integrated in a same semiconductor chip, one or a plurality of GO1-type transistors, one or a plurality of GO2-type transistors, and one or a plurality of transistors 50 or 51.

FIGS. 4A and 4B illustrate additional steps that can be performed between the steps illustrated in FIGS. 1C and 1D.

More specifically, FIG. 4A illustrates a step for cleaning the sides of the conductive gate layer 17.

In this step, the layer 130 formed on the sides of the conductive gate layer 17 is removed. In this step, a portion of the gate insulator layer 13 located under the conductive gate layer 17 is also removed.

As an example, this removal is carried out in liquid phase based on hydrogen fluoride (HF) and standard clean 1 (SC1) comprising demineralized water, ammonia water and hydrogen peroxide. As an example, the base peroxide mixture removes organic residues while the HF permits the native oxide removal. At the end of this step, the sides of the conductive gate layer 17 are free of any trace of silicon oxide. Furthermore, at the end of this step, the gate insulation layer 13 has been removed over a width L3 of between 5% and 25% of the conductive gate layer 17 length.

FIG. 4B illustrates a step of deposition of a layer 55 on the sides of the conductive gate layer 17 and in the spaces formed under the conductive gate layer 17 in the previous step on both sides of the gate insulator layer.

In this step, the layer 55 is first deposited on the top and sides of the conductive gate layer 17 and on the parts of the top of the semiconductor layer 11 not covered by the insulating layer 13. As an example, the deposition of the layer 55 is performed by chemical vapor deposition, atomic layer deposition or plasma techniques based on low frequency RF power or pulsed. For example, the layer 55 is formed with a thickness between 1 nm and 400 nm, for example between 1 nm and 200 nm.

In a second step, the layer 55 is removed by anisotropic etching. As an example, the etching allows the removal of the parts of the layer 55 located on the upper face of the conductive gate layer 17 and on the upper face of the semiconductor layer 11 outside the face of the conductive gate layer 17. After the etching step, the layer 55 remains on the sides of the conductive gate layer 17 and between the conductive gate layer 17 and the semiconductor layer 11, under the extreme edges of the conductive gate 17. The layer 55 is, for example made of a material with low dielectric constant, that is a dielectric material having a dielectric constant lower than that of silicon oxide. For example, the layer 55 is made of silicon, carbon and/or oxygen comprising silicon oxycarbide having a dielectric constant lower than 3, silicoboron carbonitride, organosilicate glass, polyimides and/or porous oxides.

An advantage of the embodiment shown in FIGS. 4A and 4B is that the part of the layer 55 located between the conductive gate layer 17 and the semiconductor layer 11 reduces the overlap capacitance.

Another advantage of the embodiment shown in FIGS. 4A and 4B is that the part of the layer 55 located on the sides of the conductive gate layer 17, may act as offset spacer.

Various embodiments and variants have been described. Those skilled in the art will understand that certain features of these various embodiments and variants may be combined, and other variants will occur to those skilled in the art. In particular, the described embodiments are not limited to the examples of materials and of dimensions mentioned in the present disclosure.

Finally, the practical implementation of the described embodiments and variations is within the abilities of those skilled in the art based on the functional indications given hereabove.

1. A method for forming, in and on a semiconductor layer (11), a first transistor comprising a first gate insulator layer (132) having a first thickness (e4), a second transistor comprising a second gate insulator layer (131) of a second thickness (e3) greater than the first thickness (e4), and a third transistor comprising a third gate insulator layer (13) of variable thickness in a direction of a length (L) of the third transistor, the third gate insulation layer (13) comprising a first region having the first thickness (e4) opposite a central region of a conductive gate of the third transistor, and a second region having the second thickness (e3) facing edge regions of the conductive gate of the third transistor, the third gate insulator layer (13) having a step in thickness between the first and second regions, the process comprising the following successive steps:
a) forming a first layer of gate insulation (131) having the second thickness (e3) on an upper surface of a semiconductor layer (11) opposite locations for the first, second and third transistors;
b) locally removing the first layer of gate insulation (131) such that the surface of the semiconductor layer is exposed (11) opposite the location of the first transistor and a portion of the semiconductor layer is exposed at the first region of the location of the third transistor, said portion comprising a strip of width L1;
c) forming a second layer of gate insulation (132) having the first thickness (e4) on the upper surface of the semiconductor layer at the location of the first transistor and at the portion of the semiconductor layer exposed in step b) at the first region of the location of the third transistor in the first region.

2. The method of claim 1, further comprising, after step c), forming a conductive gate for the first transistor over the second layer of gate insulation, forming a conductive gate for the second transistor over the first layer of gate insulation, and forming a conductive gate for the third transistor over both the first and second layers of gate insulation.

3. The method of claim 2, wherein the conductive gate for the third transistor is formed over both the first and second layers of gate insulation having a band of width L greater than width L1.

4. The method according to claim 2, further comprising coating sides of the conductive gates for the first, second and third transistors with a layer of oxide.

5. The method according to claim 1, wherein the first region extends over a length of 110 to 130 nm.

6. The method according to claim 1, wherein the second region includes two parts on either side of the first region, each of the parts of the second region extending over a length of 10 nm to 30 nm.

7. The method according to claim 1, wherein a difference between the first thickness and the second thickness is greater than or equal to 2 nm.

8. A method of manufacturing an integrated circuit including a first transistor having a first gate insulator with a first thickness, a second transistor having a gate insulator with a second thickness, and a third transistor having a gate insulator with a variable thickness along a length direction of the third transistor, wherein the second thickness is greater than the first thickness, and wherein the variable thickness comprises the second thickness below edge regions of a conductive gate for the third transistor and the first thickness at a location below a center of the conductive gate, the method comprising:
forming a first gate insulator layer having the second thickness on an upper surface of a semiconductor layer at locations for the first, second and third transistors;
locally removing the first gate insulator layer to expose the upper surface of the semiconductor layer at the location of the first transistor and at the location for the center of the conductive gate for the third transistor, while leaving the first gate insulator layer in place at locations for the edge regions of the conductive gate for the third transistor;
forming a second gate insulator layer having the first thickness at the location of the first transistor and at the location for the center of the conductive gate for the third transistor; and
forming, over the first and second gate insulator layers, conductive gates for the first, second and third transistors.

9. The method of claim 8, wherein forming the first gate insulator layer comprises oxidizing the upper surface of the semiconductor layer, and wherein forming a second gate insulator layer comprises oxidizing the upper surface of the semiconductor layer.

10. The method of claim 8, wherein locally removing the first gate insulator layer comprises performing an etching.

11. The method according to claim 8, wherein a difference between the first and second thickness is greater than or equal to 2 nm.

12. A method of manufacturing a transistor, comprising:
forming a first gate insulator layer of thickness e3 on an upper surface of a semiconductor layer;
locally removing the first gate insulator layer from a first region over a strip of width L1;
forming a gate insulator layer of thickness e4 smaller than the thickness e3 on the upper surface of the semiconductor layer in the first region; and
forming a conductive gate in front of a strip of width L, greater than width L1 and including said strip of width L1.

13. The method according to claim 12, wherein a thickness of the gate insulator exhibits a step in thickness from the thickness e4 to the thickness e3 at a location under the conductive gate between the first region and a second region under the gate outside of the first region, and wherein a difference between the thickness e3 and the thickness e4 is greater than or equal to 2 nm.

14. The method according to claim 12, further comprising simultaneously forming:
a first additional transistor comprising a gate insulator layer of constant thickness e4 in the channel length direction of the first additional transistor; and
a second additional transistor comprising a gate insulator layer of constant thickness e3 in the channel length direction of the second additional transistor.

15. The method according to claim 14, wherein forming the first additional transistor comprises:
when locally removing the first gate insulator layer from the first region, also removing the first gate insulator layer from a region of the first additional transistor;
when forming the gate insulator layer of thickness e4, also forming a gate insulator layer of thickness e4 in the region of the first additional transistor; and
when forming the conductive gate, also forming a conductive gate for the first additional transistor.

16. The method according to claim 14, wherein forming the second additional transistor comprises:
when locally removing the first gate insulator layer from the first region, leaving the first gate insulator layer in place in a region of the second additional transistor; and
when forming the conductive gate, also forming a conductive gate for the second additional transistor.

17. A method of manufacturing a transistor, comprising:
depositing a gate insulator layer of a thickness e1 on an upper surface of a semiconductor layer;
forming a conductive gate on top of and in contact with a portion of the gate insulator layer; and
thermally oxidizing the gate insulator layer so that the gate insulator layer reaches a thickness e2, greater than the thickness e1, at locations below edge regions of the conductive gate and remains at the thickness e1 at a location below a center of the conductive gate.

18. The method according to claim 17, wherein a thickness of the gate insulator varies progressively the thickness e1 to the thickness e2 between the location below a center of the conductive gate and the locations below edge regions of the conductive gate, and wherein a difference between the thickness e1 and the thickness e2 is greater than or equal to 2 nm.

19. The method according to claim 17, comprising:
removing the gate insulator layer over a width L3 at location below extreme edge regions of the conductive gate; and
depositing a layer of a low dielectric constant material under the extreme edges of the conductive gate.
